(19) United States
(12) Patent Application Publication
(10) Pub. No.: US 2002/0027267 A1
(43) Pub. Date: Mar. 7, 2002

(54) Thin-type semiconductor device and die pad thereof

(76) Inventors: Chia-Yi Lin, Taichung Hsien (TW); Chih-Tsung Hou, Taichung Hsien (TW); Kung-Ming Huang, Changhwa (TW); Ching-Kun Yeh, Taichung (TW)

Correspondence Address: MR. PETER F. CORLESS, EDWARDS & ANGELL, LLP, 101 FEDERAL STREET, BOSTON, MA, 02110, US

(21) Appl. No.: 09/910,278

(22) Filed: Jul. 19, 2001

(30) Foreign Application Priority Data
Sep. 7, 2000 (TW) 89118298

(51) Int. Cl. H01L 23/495

(52) U.S. Cl. 257/666

(57) ABSTRACT

A thin-type semiconductor device and a die pad thereof are proposed. The thin-type semiconductor device includes a semiconductor chip, a die pad, a plurality of leads and an encapsulant. With the use of a strengthening structure formed on a side surface of the die pad and/or on a first surface of the die pad other than an area for attaching the chip thereto, adherence between the die pad and the encapsulant can be enhanced, as well as delamination between the die pad and the encapsulant or crack in the encapsulant can be prevented from occurrence, and accordingly credibility and reliability of the semiconductor device can be assured.

### FIELD OF THE INVENTION

The present invention relates to thin-type semiconductor devices and chip carriers thereof, and more particularly, to a thin-type semiconductor device and a chip carrier thereof, in which credibility and reliability of the semiconductor device can be assured.

### BACKGROUND OF THE INVENTION

As shown in FIG. 1, a conventional semiconductor device 1 has a semiconductor chip 10 with a first surface 10a and a second surface 10b, a die pad 11 with a first surface 11a and a second surface 11b, a plurality of leads 12 disposed around the chip 10, and an encapsulant 15 for encapsulating the chip 10, the die pad 11 and inner portions 12a of the leads 12 therein. The chip 10, having the second surface 10b thereof attached to the first surface 11a of the die pad 11, is electrically connected to the leads 12 through a plurality of metal wires 13 such as gold wires. Further, exposed portions 12b of the leads 12 exposed out of the encapsulant 15 are formed in a gull wing shape for being disposed on a substrate such as a printed circuit board (not shown). Moreover, bottom ends of the exposed portions 12b are welded to corresponding circuits on the substrate, allowing the chip 10 to be electrically connected to the substrate through the metal wires 13 and the leads 12.

However, the two-side molded semiconductor device 1 has a certain overall thickness t1 accomplished by the two-sided encapsulant 15, which makes the semiconductor device 1 not sufficiently small in size and light in weight as required for a consumptive electronic product, such as a communicating product. Moreover, the exposed portions 12b of the leads 12 occupy usable area on the printed circuit board, which lower the layout density of the semiconductor devices on the printed circuit board, and further reduce the performance of the electronic product.

As a result, one-side molded semiconductor devices 2a and 2b are proposed for minimizing the overall thickness of the semiconductor device and reducing the occupied area of the semiconductor device on the printed circuit board, as illustrated in FIGS. 2 and 3. Referring to FIG. 2, the thin-type semiconductor device 2a also has a semiconductor chip 20 with a first surface 20a and a second surface 20b, a die pad 21 with a first surface 21a and a second surface 21b, a plurality of leads 22 disposed around the die pad 21, and an encapsulant 25 for partially encapsulating the chip 20, the die pad 21 and the leads 22. The chip 20, having the second surface 20b thereof attached to the first surface 21a of the die pad 21, is electrically connected to the leads 12 through a plurality of metal wires 23 such as gold wires. The difference between the thin-type semiconductor device 2a and the semiconductor device 1 of FIG. 1 is that the encapsulant 25 of the semiconductor device 2a only encapsulates one side of the die pad 21 and one side of the leads 22, with the second surface 21b of the die pad 21 and a backside surface 22b of the leads 22 being exposed to the atmosphere, wherein the backside surface 22b of the leads 22 is substantially aligned with the second surface 21b of the die pad 21. Further, outside ends of the leads 22 are substantially aligned with an outer edge of the encapsulant 25, so that there is no such gull wing-shaped leads for the semiconductor device 2a as those illustrated in FIG. 1 for protruding out of the encapsulant 15 and extending downwardly over a bottom edge of the encapsulant 15. Therefore, the semiconductor device 2a of FIG. 2 has an overall thickness t2a smaller than the thickness t1 of the semiconductor device 1 of FIG. 1 by a difference t0 representing the thickness for the part below the die pad 11 of the semiconductor device 1, that is, t2a=t1−t0. Furthermore, the leads 22 with no exposed portions as those of FIG. 1 can thus greatly raise the layout density of the semiconductor devices on the printed circuit board. Moreover, heat generated by the chip 20 can be directly dissipated to the atmosphere through the exposed surface of the die pad 21, and thus the heat-dissipating efficiency can be effectively increased.

FIG. 3 illustrates another one-side molded thin-type semiconductor device 2b, which is structurally identical to the semiconductor device 2a of FIG. 2 except the electric connection between the chip 20 and leads 22a. In the semiconductor device 2b, the leads 22a extend inwardly and upwardly to a position above the first surface 20a of the chip 20, and then the leads 22a are electrically connected to the first surface 20a of the chip 2 through solder balls 24 by the tape automated bonding (TAB) technique. As a result, unlike the semiconductor device 2a of FIG. 2 for predefining a safe thickness tsa between a loop top of the metal wires 23 and a top edge of the encapsulant 25, in application of the TAB technique, the thickness tsb of the encapsulant 25 above the chip 20 in FIG. 3 can be reduced, even to zero, if necessary. That is, an upper surface 22c of the leads 22a can be exposed out of the encapsulant 25 (not shown). This makes the thickness t2b of the semiconductor device 2b to be further reduced, and such a semiconductor device 2b is more suitably applied to super-thin type pioneer products.

However, the foregoing one-side molded semiconductor devices 2a and 2b may generate a problem of delamination occurring between the die pad 21 and the encapsulant 25, due to decreased adhesive area between the die pad 21 and the encapsulant 25, and thus quality and reliability of products can be significantly degraded. In addition, the partially exposed die pad may allow moisture to slowly penetrate into the interior of the device along a side surface of the die pad 21 and accumulate in small gaps between the die pad 21 and the encapsulant 25. As a result, the accumulated moisture, which evaporates due to heat generated by the chip 20 in operation, significantly increases in volume after evaporation and enlarges the gaps between the die pad 21 and the encapsulant 25, and thus the encapsulant 25 is damaged with crack being generated.

### SUMMARY OF THE INVENTION

A primary objective of the present invention is to provide a thin-type semiconductor device and a die pad thereof, in which strong adherence between the die pad and an encapsulant is assured so as to prevent delamination or crack from occurrence and improve reliability and quality for the semiconductor device.

In accordance with the foregoing and other objectives, the thin-type semiconductor device of the invention comprises a semiconductor chip having a first surface and a second surface; a die pad having a first surface and a second surface, wherein the second surface of the chip is attached to the first surface of the die pad; a plurality of leads disposed around the die pad and electrically connected to the first surface of the chip; and an encapsulant for encapsulating the chip, the die pad, and the leads, with at least the second surface of the die pad and a surface of the leads being exposed to the atmosphere, wherein the surface of the leads are aligned with the second surface of the die pad. Beside, at least on a side surface of the die pad and on the first surface of the die pad other than area for attaching the chip thereto there is formed a strengthening structure, so as to enhance adherence and prevent delamination or crack from occurring between the die pad and the encapsulant, so that quality and reliability of products can be assured.

The foregoing strengthening structure includes a plurality of recess holes formed by an etching process, or patterns, protrusions or a ripple-shaped structure formed by other mechanical process, so as to increase contact area for adherence between the die pad and the encapsulant for preventing the delamination from occurrence. In addition, the strengthening structure elongates a path for external moisture penetrating into the semiconductor device, and accordingly the moisture is impeded to enter or accumulate in the device, and thus the crack occurring in the encapsulant can be eliminated.

### BRIEF DESCRIPTION OF THE DRAWINGS

The present invention may best be understood through the following description with reference to the accompanying drawings, in which:

FIG. 1 (PRIOR ART) is a schematic diagram of a conventional semiconductor device;

FIG. 2 (PRIOR ART) is a schematic diagram of a conventional thin-type semiconductor device;

FIG. 3 (PRIOR ART) is a schematic diagram of another conventional thin-type semiconductor device;

FIG. 4 is a schematic diagram of the first preferred embodiment of the thin-type semiconductor device of the invention;

FIG. 5 is a schematic diagram of the second preferred embodiment of the thin-type semiconductor device of the invention;

FIG. 6A is a top view of the first preferred embodiment of the die pad of the invention;

FIG. 6B is a sectional view of the first preferred embodiment in FIG. 6A;

FIG. 7A is a top view of the second preferred embodiment of the die pad of the invention;

FIG. 7B is a sectional view of the second preferred embodiment in FIG. 7A;

FIG. 8 is a sectional view of the third preferred embodiment of the die pad of the invention;

FIG. 9 is a sectional view of the fourth preferred embodiment of the die pad of the invention;

FIG. 10 is a sectional view of the fifth preferred embodiment of the die pad of the invention;

FIG. 11 is a sectional view of the sixth preferred embodiment of the die pad of the invention;

FIG. 12 is a sectional view of the seventh preferred embodiment of the die pad of the invention;

FIG. 13 is a sectional view of the eighth preferred embodiment of the die pad of the invention; and

FIGS. 14A-14C are schematic diagrams showing the manufacturing process for the ninth preferred embodiment of the die pad of the invention.

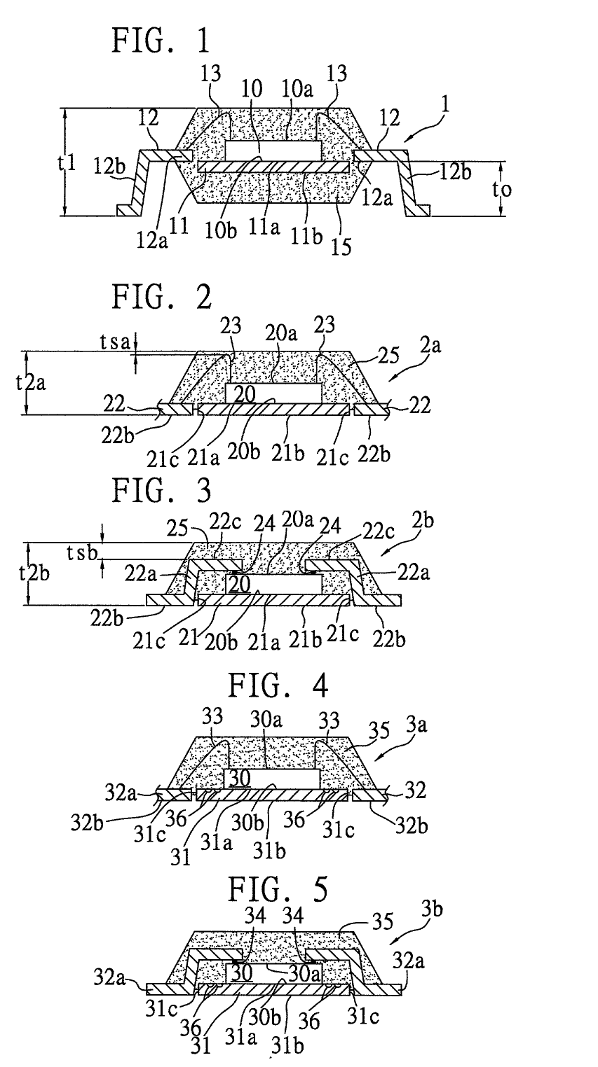

### DETAILED DESCRIPTION OF THE PREFERRED EMBODIMENT

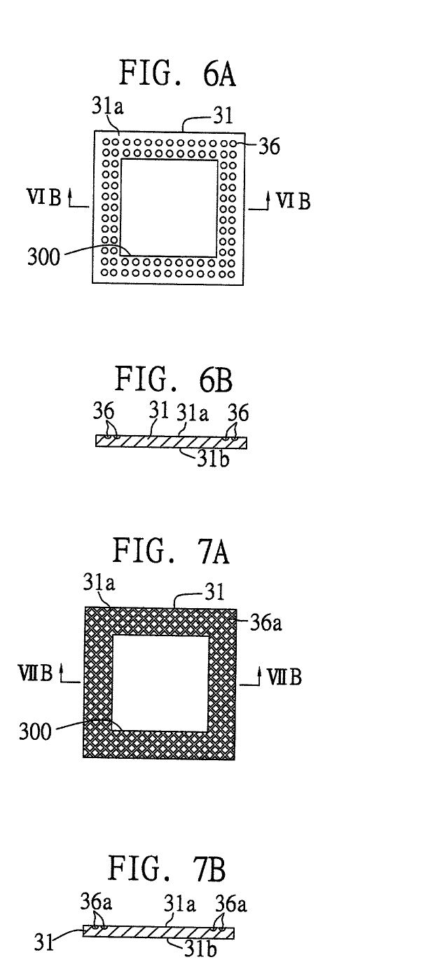

Referring to FIG. 4, the first preferred embodiment of the thin-type semiconductor device 3a of the present invention comprises a semiconductor chip 30 having a first surface 30a and a second surface 30b; a die pad 31 having a first surface 31a and a second surface 31b; a plurality of leads 32 disposed around the die pad 31; and an encapsulant 35 for encapsulating the chip 30, the die pad 31 and the leads 32, with at least the second surface 31b of the die pad 31 and a surface 32b of the leads 32 being exposed to the atmosphere, wherein the surface 32b is aligned with the second surface 31b of the die pad 31. The chip 30, having the second surface 30b thereof attached to the first surface 31a of the die pad 31, is electrically connected to the leads 32 through metal wires 33 such as gold wires, wherein the metal wires 33 each has two ends thereof respectively welded at the first surface 30a of the chip 30 and the corresponding lead 32. Moreover, on the first surface 31a of the die pad 31 other than area 300 for attaching the chip 30 thereto, there is formed a strengthening structure 36. As shown in FIGS. 6A and 6B, the strengthening structure 36 is formed as a plurality of recess holes for increasing contact area for adherence between the die pad 31 and the encapsulant 35 so as to prevent delamination from occurrence. Besides an etching process used for forming the recess hoes, the strengthening structure 36 can also be formed by applying other mechanical processes such as stamping.

Referring to FIG. 5, the second preferred embodiment of the thin-type semiconductor device 3b of the invention is substantially identical in structure to the semiconductor device 3a of FIG. 4 except the electric connection between the semiconductor chip 30 and leads 32a. In the semiconductor device 3b, the leads 32a extend inwardly and upwardly to a position above the first surface 30a of the chip 30, and are electrically connected to the first surface 30a of the chip 30 through solder balls 34 by means of a tape automated bonding (TAB) technique. As such, the semiconductor device 3b, similar as the foregoing conventional device 2b in FIG. 3, can be further reduced in thickness for being more suitably applied to super-thin type electronic products. Furthermore, the semiconductor device 3b is also provided with the die pad 31 having the strengthening structure 36 with a plurality of recess holes as those shown in FIGS. 6A and 6B, so as to increase contact area for adherence between the die pad 31 and the encapsulant 35 for preventing delamination from occurrence.

Moreover, besides the recess holes in FIGS. 6A and 6B, the strengthening structure 36 can also be in various forms, such as a patterned structure 36a with a plurality of recesses, as illustrated in FIGS. 7A and 7B. The patterned structure is formed by using a conventional mechanical process, and has its pattern not being limited to a grid pattern shown in FIG. 7A; contrarily, all other commonly used patterns in the art can be adopted.

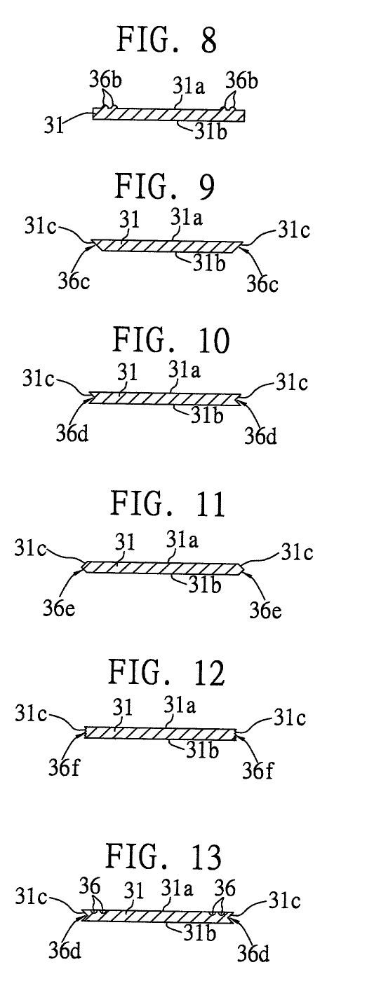

In addition, the strengthening structure formed on the die pad 31 is not limited to the recess holes or recesses in FIG. 6B or 7B; besides, the same purpose for enhancing the adherence between the die pad and the encapsulant can be achieved by forming a plurality of protrusions used as a strengthening structure 36, as illustrated in FIG. 8. Similarly, the patterned strengthening structure 36a in FIG. 7A can also be replaced by a structure with protrusions.

Further, besides other than the area on the first surface 31a of the die pad 31 for chip attachment, the strengthening structure of the invention can also be formed on a side surface 31c of the die pad 31, as shown in FIGS. 9 and 12. Referring to FIG. 9, a strengthening structure 36c is formed as an inclined structure on the side surface 31c of the die pad 31 for increasing the contact area between the side surface 31c and the encapsulant 35. Moreover, the adherence between the die pad 31 and the encapsulant can be further enhanced by engaging the strengthening structure 36c with the encapsulant 35 through a flange of the structure 36c adjacent to the first surface 31a of the die pad 31.

Referring to FIG. 10, a strengthening structure 36d having an inward re-entrant cross section is formed on the side surface 31c of the die pad 31 for increasing the contact area between the side surface 31c and the encapsulant 35, and for further enhancing the adherence between the die pad 31 and the encapsulant 35 through flanges at two ends of the structure 36d being engaged with the encapsulant 35.

A strengthening structure 36e in FIG. 11 has an outward salient structure complementing the re-entrant strengthening structure in FIG. 10, and a strengthening structure 36f in FIG. 12 is formed in a saw ripple-shaped structure. Both the structures 36e and 36f are used to increase the contact area between the side surface 31c of the die pad 31 and the encapsulant 35. Similarly, flanges of the structures 36e and 36f are engaged with the encapsulant 35 for further enhancing the adherence between the die pad 31 and the encapsulant 35.

In addition, the various strengthening structures formed on the side surface 31c of the die pad 31, as shown in FIGS. 9 to 12, not only increase the contact area between the die pad 31 and the encapsulant 35, but also elongate a path for moisture penetrating into the internal device along the side surface 31c of the die pad 31, so as to prevent the moisture from entering or accumulating in the internal device and to effectively eliminate crack occurring in the encapsulant 35.

Further referring to FIG. 13, the strengthening structure of the invention can be simultaneously formed on the side surface 31c of the die pad 31 and on the first surface 31a of the die pad 31 other than the area used for attaching the chip 30 thereon, which can further increase the contact area between the die pad 31 and the encapsulant 35 and elongate the path for external moisture entering into the internal device, allowing delamination and crack to be prevented from occurring in the encapsulant 35. In the embodiment of FIG. 13, the strengthening structure formed on the first surface 31a of the die pad 31 is identical to the strengthened structure 36 with recess holes in FIGS. 6A and 6B, and the strengthening structure formed on the side surface 31c of the die pad 31 is same in structure as the re-entrant strengthening structure 36d in FIG. 10. However, the strengthening structures in FIG. 13 are not limited to those shown in the drawing, but rather include various combinations of the strengthening structures 36, 36a and 36b shown in FIGS. 6-8 and the structures 36c, 36d, 36e and 36f shown in FIGS. 9-12. Moreover, the foregoing strengthening structures 36, 36a and 36b can be optionally formed on the side surface 31c of the die pad 31, whereas the strengthening structures 36c, 36d, 36e and 36f can also be optionally provided on the first surface 31a of the die pad 31.

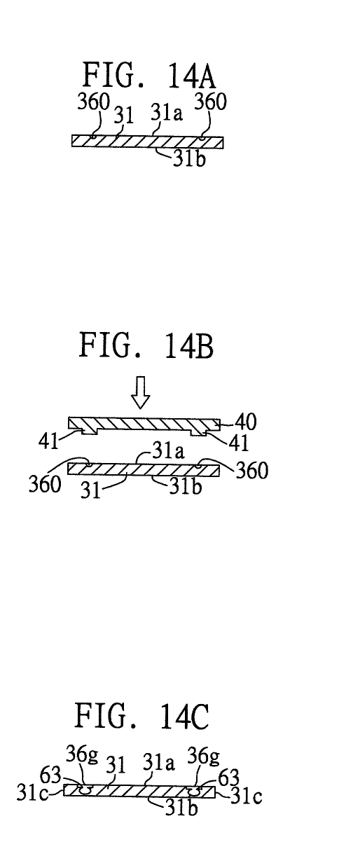

Furthermore, another strengthening structure 36g with recess holes is illustrated in FIG. 14C. On an inner surface of the strengthening structure 36g, there is additionally formed a neck 63, which helps increase the contact area between the die pad 31 and the encapsulant 35 as well as greatly strengthens the adherence between the die pad 31 and the encapsulant 35 by using the neck 63 for locking the encapsulant 35. The process for forming the strengthening structure 36g with the neck 63 is shown in FIGS. 14A-14C, First, a plurality of recess holes 360 identical to those shown in FIGS. 6A-6B are formed by an etching or stamping process on the first surface 31a of the die pad 31 other than the area used for attaching the chip 30 thereon, as illustrated in FIG. 14A. Thereafter, referring to FIG. 14B, a stamping tool 40 with stamping protrusions 41 larger in diameter than the recess holes 360 is used to slightly stamp the recess holes 360 for extruding and deforming opening edges of the recess holes 360 toward the center of the row holes 360, so as to form the necks 63 shown in FIG. 14C. The die pad 31 having the strengthening structure 36g can also be optionally provided with any of the strengthening structure 36c, 36d, 36e or 35f formed on the side surface 31c thereof so as to further enhance the adherence between the die pad 31 and the encapsulant 35 for preventing delamination and crack from occurrence. Besides, the recess hole with the neck 63 can also be optionally formed on the side surface of the die pad for the same foregoing purpose.

In conclusion, the semiconductor device of the invention having the strengthening structure formed on the die pad allows the delamination to be prevented from occurring between the die pad and the encapsulant as well as effectively prevents the crack from being generated in the encapsulant, so that the reliability and credibility for products are significantly raised.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A thin-type semiconductor device, comprising:
a semiconductor chip having a first surface and a second surface;
a die pad having a first surface and a second surface, wherein the second surface of the semiconductor chip is attached to the first surface of the die pad, and on a side surface of the die pad and on the first surface of the die pad other than an area used for attaching the chip thereon, there is formed a strengthening structure;
a plurality of leads disposed around the die pad and electrically connected to the first surface of the chip; and
an encapsulant for encapsulating the chip, the die pad, and the leads, allowing at least the second surface of the die pad and a surface of the leads aligned with the second surface of the die pad to be exposed to the atmosphere.

2. The thin-type semiconductor device of claim 1, further comprising a plurality of metal wires each having two ends thereof being respectively welded at the first surface of the chip and the corresponding lead for electrically connecting the chip and the leads.

3. The thin-type semiconductor device of claim 1, wherein the leads extend inwardly and upwardly to a position above the first surface of the chip, allowing a plurality of solder balls to be used for electrically connecting the chip and the leads by a TAB (tape automated bonding) technique.

4. The thin-type semiconductor device of claim 1, wherein the strengthening structure includes a plurality of recess holes.

5. The thin-type semiconductor device of claim 1, wherein the strengthening structure includes a patterned structure with recesses.

6. The thin-type semiconductor device of claim 1, wherein the strengthening structure includes a plurality of protrusions.

7. The thin-type semiconductor device of claim 1, wherein the strengthening structure includes a patterned structure with protrusions.

8. The thin-type semiconductor device of claim 1, wherein the strengthening structure includes a structure with an inclined surface.

9. The thin-type semiconductor device of claim 1, wherein the strengthening structure includes a structure with a re-entrant cross section.

10. The thin-type semiconductor device of claim 1, wherein the strengthening structure includes a structure with a salient cross section.

11. The thin-type semiconductor device of claim 1, wherein the strengthening structure includes a saw ripple-shaped structure.

12. The thin-type semiconductor device of claim 1, wherein the strengthening structure includes a plurality of recess holes with necks.

13. A die pad, for being used in a thin-type semiconductor device, comprising a first surface, a second surface and a side surface, wherein the first surface is used for attaching a semiconductor chip thereto, and at least on the side surface and on the first surface other than an area for the chip attachment, there is formed a strengthening structure.

14. The die pad of claim 13, wherein the strengthening structure includes a plurality of recess holes.

15. The die pad of claim 13, wherein the strengthening structure includes a patterned structure with recesses.

16. The die pad of claim 13, wherein the strengthening structure includes a plurality of protrusions.

17. The die pad of claim 13, wherein the strengthening structure includes a patterned structure with protrusions.

18. The die pad of claim 13, wherein the strengthening structure includes a structure with an inclined surface.

19. The die pad of claim 13, wherein the strengthening structure includes a structure with a re-entrant cross section.

20. The die pad of claim 13, wherein the strengthening structure includes a structure with a salient cross section.

21. The die pad of claim 13, wherein the strengthening structure includes a saw ripple-shaped structure.

22. The die pad of claim 13, wherein the strengthening structure includes a plurality of recess holes with necks.
